(19) United States
(12) Patent Application Publication
(10) Pub. No.: US 2014/0252376 A1
(43) Pub. Date: Sep. 11, 2014

(54) SILICON CARBIDE SUBSTRATE, METHOD FOR MANUFACTURING SAME AND METHOD FOR MANUFACTURING SILICON CARBIDE SEMICONDUCTOR DEVICE

(71) Applicant: Sumitomo Electric Industries, Ltd., Osaka-shi (JP)

(72) Inventor: Satomi ITOH, Osaka-shi (JP)

(73) Assignee: Sumitomo Electric Industries, Ltd., Osaka-shi (JP)

(21) Appl. No.: 14/197,957

(22) Filed: Mar. 5, 2014

(30) Foreign Application Priority Data
Mar. 5, 2013 (JP) 2013-043042

(51) Int. Cl. H01L 29/16; H01L 21/02

(52) U.S. Cl. CPC H01L 29/1608; H01L 21/02529
USPC 257/77; 438/507

(57) ABSTRACT

A method for manufacturing a silicon carbide substrate includes the following steps. A silicon carbide single-crystal substrate is prepared. A silicon carbide epitaxial layer is formed in contact with the silicon carbide single-crystal substrate. A silicon layer is formed in contact with a second surface of the silicon carbide epitaxial layer opposite to a first surface thereof that makes contact with the silicon carbide single-crystal substrate. Accordingly, there are provided a silicon carbide substrate, a method for manufacturing the silicon carbide substrate, and a method for manufacturing a silicon carbide semiconductor device so as to achieve prevention of contamination of a silicon carbide epitaxial layer in a simple manner.

### BACKGROUND OF THE INVENTION

1. Field of the Invention

The present invention relates to a silicon carbide substrate, a method for manufacturing the silicon carbide substrate, and a method for manufacturing a silicon carbide semiconductor device, in particular, a silicon carbide substrate, a method for manufacturing the silicon carbide substrate, and a method for manufacturing a silicon carbide semiconductor device, so as to achieve prevention of contamination of a silicon carbide epitaxial layer.

2. Description of the Background Art

In recent years, silicon carbide has begun to be adopted as a material for a semiconductor device in order to attain high breakdown voltage and low loss in a semiconductor device such as a MOSFET (Metal Oxide Semiconductor Field Effect Transistor) or a SBD (Schottky Barrier Diode) as well as use thereof under high temperature environment. Silicon carbide is a wide band gap semiconductor having a band gap larger than that of silicon, which has been conventionally widely used as a material for semiconductor devices. Hence, by adopting silicon carbide as a material for a semiconductor device, the semiconductor device can have a high breakdown voltage, reduced on-resistance, and the like. Further, the semiconductor device thus adopting silicon carbide as its material has properties less deteriorated even under a high temperature environment than those of a semiconductor device adopting silicon as its material, advantageously.

As a method for removing particles attached to a surface of a silicon substrate, silicon of the outermost surface of the substrate is oxidized and the particles are then removed by removing the silicon oxide film. However, silicon carbide is less likely to be oxidized as compared with silicon, so that the method for cleaning a silicon substrate cannot be simply applied to a silicon carbide substrate. For example, as a method for cleaning a silicon carbide substrate, Japanese Patent Laying-Open No. 2012-4270 describes a method of forming an oxide film in a dry atmosphere including oxygen element and removing the oxide film.

However, in the cleaning method described in Japanese Patent Laying-Open No. 2012-4270, the silicon carbide substrate needs to be heated to 700° C. or more so as to form the oxide film. This requires an additional process of heating the silicon carbide substrate in order to prevent contamination of an epitaxial layer by cleaning the silicon carbide substrate. This leads to complicated cleaning process for the silicon carbide substrate.

### SUMMARY OF THE INVENTION

The present invention has been made in view of the foregoing problem, and has its object to provide a silicon carbide substrate, a method for manufacturing the silicon carbide substrate, and a method for manufacturing a silicon carbide semiconductor device so as to achieve prevention of contamination of a silicon carbide epitaxial layer in a simple manner.

A method for manufacturing a silicon carbide substrate in the present invention includes the following steps. A silicon carbide single-crystal substrate is prepared. A silicon carbide epitaxial layer is formed in contact with the silicon carbide single-crystal substrate. A silicon layer is formed in contact with a second surface of the silicon carbide epitaxial layer opposite to a first surface thereof that makes contact with the silicon carbide single-crystal substrate.

A silicon carbide substrate in the present invention includes a silicon carbide single-crystal substrate; a silicon carbide epitaxial layer, and a silicon layer. The silicon carbide epitaxial layer is provided in contact with the silicon carbide single-crystal substrate. The silicon layer is provided in contact with a second surface of the silicon carbide epitaxial layer opposite to a first surface thereof that makes contact with the silicon carbide single-crystal substrate.

According to the present invention, there can be provided a silicon carbide substrate, a method for manufacturing the silicon carbide substrate, and a method for manufacturing a silicon carbide semiconductor device so as to achieve prevention of contamination of a silicon carbide epitaxial layer in a simple manner.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic cross sectional view schematically showing a structure of a silicon carbide substrate according to a first embodiment of the present invention.

FIG. 2 is a flowchart schematically showing a method for manufacturing the silicon carbide substrate according to the first embodiment of the present invention.

FIG. 3 is a schematic cross sectional view schematically showing a first step of the method for manufacturing the silicon carbide substrate according to the first embodiment of the present invention.

FIG. 4 is a schematic cross sectional view schematically showing a second step of the method for manufacturing the silicon carbide substrate according to the first embodiment of the present invention.

FIG. 5 shows a relation between temperature and time in an epitaxial layer forming step and a silicon layer forming step.

FIG. 6 shows a relation between a flow rate of carrier gas and time in the epitaxial layer forming step and the silicon layer forming step.

FIG. 7 shows a relation between a flow rate of silicon carbide source material gas and time in the epitaxial layer forming step and the silicon layer forming step.

FIG. 8 shows a relation between a flow rate of silicon source material gas and time in the epitaxial layer forming step and the silicon layer forming step.

FIG. 9 is a schematic cross sectional view schematically showing a structure of a silicon carbide semiconductor device according to a second embodiment of the present invention.

FIG. 10 is a flowchart schematically showing a method for manufacturing the silicon carbide semiconductor device according to the second embodiment of the present invention.

FIG. 11 is a schematic cross sectional view schematically showing a first step of the method for manufacturing the silicon carbide semiconductor device according to the second embodiment of the present invention.

FIG. 12 is a schematic cross sectional view schematically showing a second step of the method for manufacturing the silicon carbide semiconductor device according to the second embodiment of the present invention.

FIG. 13 is a schematic cross sectional view schematically showing a third step of the method for manufacturing the silicon carbide semiconductor device according to the second embodiment of the present invention.

### DESCRIPTION OF THE PREFERRED EMBODIMENTS

The following describes embodiments of the present invention with reference to figures. It should be noted that in the below-mentioned figures, the same or corresponding portions are given the same reference characters and are not described repeatedly.

Described first is the gist of the embodiments with regard to (i) to (xii) below.

(i) A method for manufacturing a silicon carbide substrate 100 in the present embodiment includes the following steps. A silicon carbide single-crystal substrate 11 is prepared. A silicon carbide epitaxial layer 13 is formed in contact with silicon carbide single-crystal substrate 11. A silicon layer 2 is formed in contact with a second surface 13a of silicon carbide epitaxial layer 13 opposite to a first surface 13b thereof that makes contact with silicon carbide single-crystal substrate 11.

According to the method for manufacturing silicon carbide substrate 100 in the present embodiment, silicon layer 2 is formed in contact with second surface 13a of silicon carbide epitaxial layer 13. In this way, even when silicon carbide substrate 100 is stored under atmospheric air for a long period of time, light metal impurities, such as sodium and potassium, or organic impurities can be prevented from being attached to second surface 13a of silicon carbide epitaxial layer 13. Accordingly, silicon carbide epitaxial layer 13 can be prevented from being contaminated.

(ii) Preferably in the method for manufacturing silicon carbide substrate 100 in the present embodiment, silicon layer 2 has a thickness of not more than 0.5 μm. Accordingly, silicon layer 2 can be removed readily. Moreover, productivity in manufacturing silicon carbide substrate 100 can be improved.

(iii) Preferably in the method for manufacturing silicon carbide substrate 100 in the present embodiment, the step of forming silicon carbide epitaxial layer 13 and the step of forming silicon layer 2 are performed in the same chamber. Accordingly, silicon carbide epitaxial layer 13 can be effectively prevented from being contaminated.

(iv) A method for manufacturing a silicon carbide semiconductor device 1 in the present embodiment includes the following steps. Silicon carbide substrate 100 is prepared which is manufactured using the method recited in one of (i) to (iii) described above. Silicon layer 2 is removed.

According to the method for manufacturing silicon carbide semiconductor device 1 in the present embodiment, silicon layer 2 is formed in contact with second surface 13a of silicon carbide epitaxial layer 13. Accordingly, silicon carbide epitaxial layer 13 can be prevented from being contaminated. This suppresses property deterioration of silicon carbide semiconductor device 1.

(v) Preferably in the method for manufacturing silicon carbide semiconductor device 1 in the present embodiment, the step of removing silicon layer 2 is performed through wet etching on silicon layer 2 using hydrofluoric-nitric acid. Accordingly, silicon layer 2 can be removed efficiently.

(vi) Preferably in the method for manufacturing silicon carbide semiconductor device 1 in the present embodiment, after the step of removing the silicon layer, an electrode 4 is formed on second surface 13a of silicon carbide epitaxial layer 13. Accordingly, electrode 4 is formed on second surface 13a of silicon carbide epitaxial layer 13 thus prevented from being contaminated, thereby preventing property deterioration of electrode 4. It should be noted that electrode 4 may be formed in contact with second surface 13a of silicon carbide epitaxial layer 13, or may be formed on second surface 13a of silicon carbide epitaxial layer 13 with another layer being interposed therebetween.

(vii) A silicon carbide substrate 100 in the present embodiment includes a silicon carbide single-crystal substrate 11, a silicon carbide epitaxial layer 13, and a silicon layer 2. Silicon carbide epitaxial layer 13 is provided in contact with silicon carbide single-crystal substrate 11. Silicon layer 2 is provided in contact with second surface 13a of silicon carbide epitaxial layer 13 opposite to first surface 13b thereof that makes contact with silicon carbide single-crystal substrate 11. In this way, even when silicon carbide substrate 100 is stored under atmospheric air for a long period of time, light metal impurities, such as sodium and potassium, or organic impurities can be prevented from being attached to second surface 13a of the silicon carbide epitaxial layer. Accordingly, silicon carbide epitaxial layer 13 can be prevented from being contaminated.

(viii) Preferably in silicon carbide substrate 100 in the present embodiment, silicon layer 2 has a thickness of not more than 0.5 μm. Accordingly, silicon layer 2 can be removed readily. Moreover, productivity in manufacturing silicon carbide substrate 100 can be improved.

(ix) Preferably in silicon carbide substrate 100 in the present embodiment, silicon layer 2 entirely covers second surface 13a of silicon carbide epitaxial layer 13. Accordingly, second surface 13a of silicon carbide epitaxial layer 13 can be entirely protected, thereby more effectively preventing contamination of silicon carbide epitaxial layer 13.

(x) A method for manufacturing a silicon carbide semiconductor device 1 in the present embodiment includes the following steps. A silicon carbide substrate 100 recited in one of (vii) to (ix) described above is prepared. Silicon layer 2 is removed.

According to the method for manufacturing silicon carbide semiconductor device 1 in the present embodiment, silicon layer 2 is formed in contact with second surface 13a of silicon carbide epitaxial layer 13. Accordingly, silicon carbide epitaxial layer 13 can be prevented from being contaminated. This suppresses property deterioration of silicon carbide semiconductor device 1.

(xi) Preferably in the method for manufacturing silicon carbide semiconductor device 1 in the present embodiment, the step of removing silicon layer 2 is performed through wet etching on silicon layer 2 using hydrofluoric-nitric acid. Accordingly, silicon layer 2 can be removed efficiently.

(xii) Preferably in the method for manufacturing silicon carbide semiconductor device 1 in the present embodiment, after the step of removing silicon layer 2, an electrode 4 is formed on second surface 13a of silicon carbide epitaxial layer 13. Accordingly, electrode 4 is formed on second surface 13a of silicon carbide epitaxial layer 13 thus prevented from being contaminated, thereby preventing property deterioration of electrode 4. It should be noted that electrode 4 may be formed in contact with second surface 13a of silicon carbide epitaxial layer 13, or may be formed on second surface 13a of silicon carbide epitaxial layer 13 with another layer being interposed therebetween.

The following describes the embodiments of the present invention more in detail.

### First Embodiment

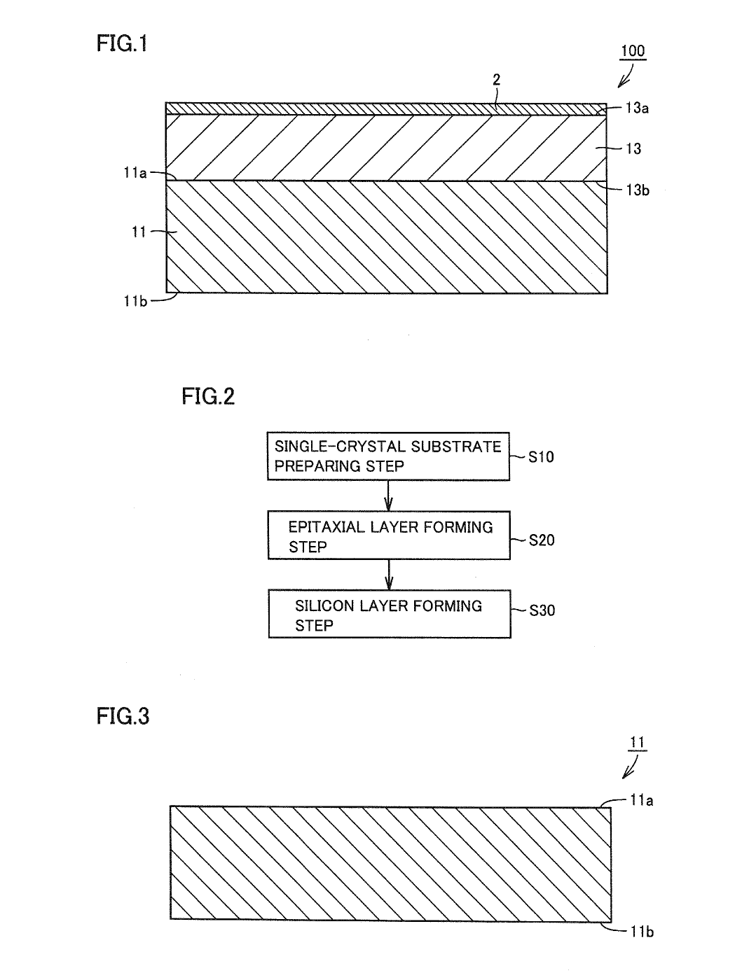

Referring to FIG. 1, the following describes a configuration of a silicon carbide substrate 100 according to the present embodiment. Silicon carbide substrate 100 according to the present embodiment mainly has a silicon carbide single-crystal substrate 11, a silicon carbide epitaxial layer 13, and a silicon layer 2. Silicon carbide single-crystal substrate 11 is formed of hexagonal crystal silicon carbide such as polytype 4H. Silicon carbide single-crystal substrate 11 includes an impurity element such as nitrogen. Silicon carbide single-crystal substrate 11 has n type conductivity. The impurity, such as nitrogen, in silicon carbide single-crystal substrate 11 has a concentration of, for example, not less than about 1×10¹⁸ cm⁻³ and not more than about 1×10¹⁹ cm⁻³. Silicon carbide single-crystal substrate 11 has a first main surface 11b and a second main surface 11a opposite to first main surface 11b.

Silicon carbide epitaxial layer 13 is provided in contact with second main surface 11a of silicon carbide single-crystal substrate 11. Silicon carbide epitaxial layer 13 has a thickness of, for example, not less than about 5 μm and not more than about 40 μm. Silicon carbide epitaxial layer 13 includes an impurity element such as nitrogen, and silicon carbide epitaxial layer 13 has n type conductivity. Silicon carbide epitaxial layer 13 may have an impurity concentration lower than that of silicon carbide single-crystal substrate 11. For example, the impurity concentration of silicon carbide epitaxial layer 13 is not less than about 1×10¹⁵ cm⁻³ and not more than about 1×10¹⁶ cm⁻³. Further, silicon carbide epitaxial layer 13 may have a dislocation density lower than that of silicon carbide single-crystal substrate 11. Silicon carbide epitaxial layer 13 has a first surface 13b, and a second surface 13a opposite to first surface 13b. First surface 13b of silicon carbide epitaxial layer 13 is provided in contact with second main surface 11a of silicon carbide single-crystal substrate 11.

Silicon layer 2 is provided on and in contact with second surface 13a of silicon carbide epitaxial layer 13. Silicon layer 2 is formed of silicon. Silicon layer 2 has a thickness of, for example, not less than 0.05 μm and not more than 0.1 μm, preferably, not more than 0.5 μm. Silicon layer 2 preferably covers the entire second surface 13a of silicon carbide epitaxial layer 13. It should be noted that silicon carbide substrate 100 according to the present embodiment is a substrate in a state prior to formation of an impurity region and an electrode, for example. The impurity region is formed by ion implantation or the like to have a conductivity type different from the conductivity type of silicon carbide epitaxial layer 13.

Referring to FIG. 2 to FIG. 8, the following describes a method for manufacturing the silicon carbide substrate according to the present embodiment. First, a single-crystal substrate preparing step (S10. FIG. 2) is performed. Specifically, referring to FIG. 3, an ingot (not shown) made of, for example, single-crystal silicon carbide having a polytype of 4H is sliced to prepare silicon carbide single-crystal substrate 11 having n type conductivity. Silicon carbide single-crystal substrate 11 has first main surface 11b and second main surface 11a opposite to first main surface 11b. Silicon carbide single-crystal substrate 11 includes an impurity such as nitrogen. The impurity concentration of silicon carbide single-crystal substrate 11 is not less than about 1×10¹⁸ cm⁻³ and not more than about 1×10¹⁹ cm⁻³, for example.

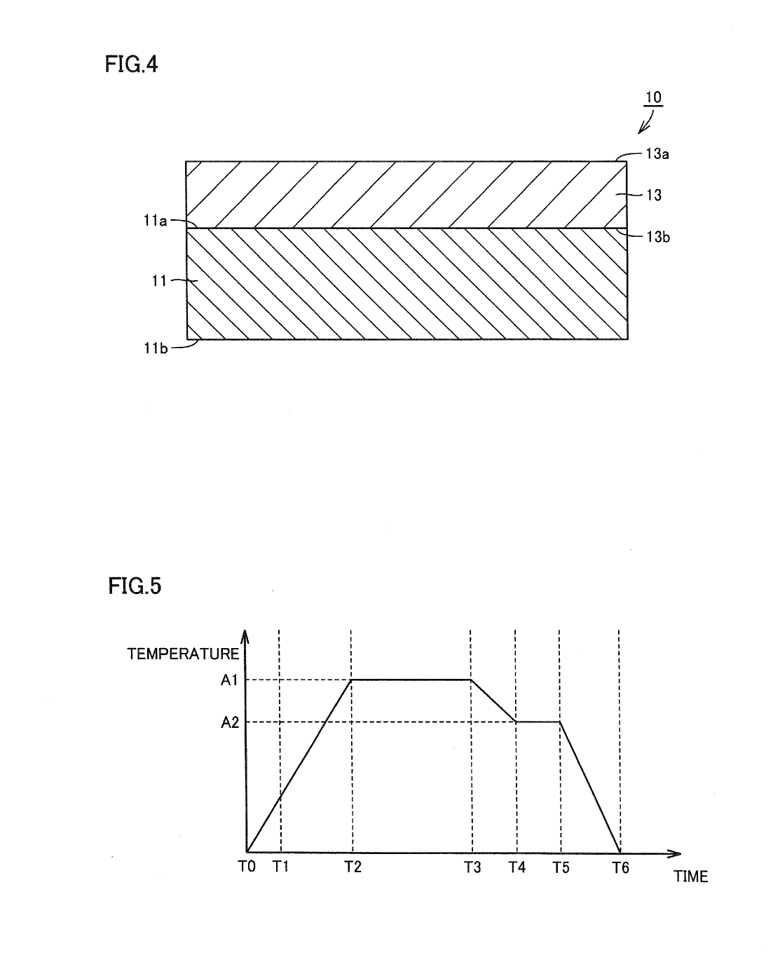

Next, an epitaxial layer forming step (S20: FIG. 2) is performed. Specifically, referring to FIG. 4, silicon carbide epitaxial layer 13 is formed in contact with second main surface 11a of silicon carbide single-crystal substrate 11, for example. Silicon carbide epitaxial layer 13 has first surface 13b and second surface 13a opposite to first surface 13b. First surface 13b of silicon carbide epitaxial layer 13 is formed in contact with second main surface 11a of silicon carbide single-crystal substrate 11.

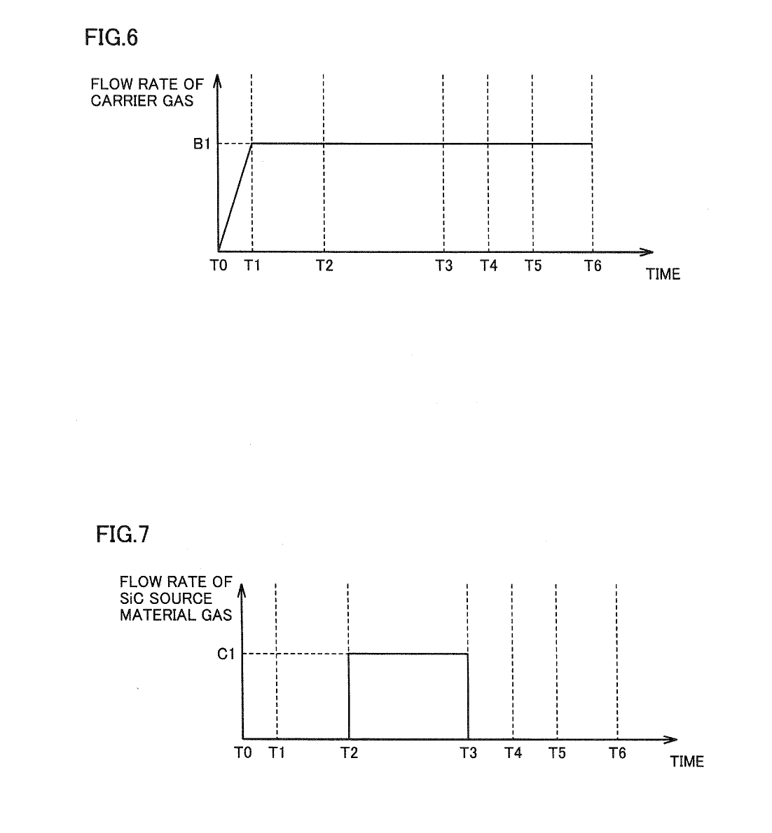

More specifically, silicon carbide single-crystal substrate 11 is first placed in a chamber (time T0). Referring to FIG. 5 and FIG. 6, carrier gas is introduced into a chamber. While increasing the flow rate of the carrier gas, the temperature of silicon carbide single-crystal substrate 11 is increased. The carrier gas introduced into the chamber is, for example, hydrogen gas. The flow rate of the hydrogen gas is about 150 slm, for example. The flow rate of the carrier gas is increased during a period of time from T0 to T1. After time T1, a substantially constant flow rate B1 is maintained. Meanwhile, the temperature of silicon carbide single-crystal substrate 11 is increased during a period of time from T0 to T2, and is maintained at a substantially constant temperature during a period of time from T2 to T3. Time T1 taken for the flow rate of the carrier gas to be constant may be shorter than time T2 taken for the temperature of silicon carbide single-crystal substrate 11 to be constant. It should be noted that the temperature of silicon carbide single-crystal substrate 11 at time T2 is, for example, not less than 1500° C. and not more than 1700° C.

Next, referring to FIG. 7, silicon carbide source material gas is introduced into the chamber at a substantially constant flow rate C1 during a period of time from T2 to T3. The silicon carbide source material gas is gas including silane (SiH₄), for example. More specifically, the silicon carbide source material gas is gas including silane, propane, nitrogen, and ammonia. The flow rate of silane is, for example, about 30 sccm to 100 sccm. The flow rate of propane is, for example, about 10 sccm to 100 sccm. The flow rate of nitrogen is, for example, about 5 sccm to 500 sccm. The flow rate of ammonia is, for example, about 5 sccm to 500 sccm. By introducing the silicon carbide source material gas into the chamber, silicon carbide epitaxial layer 13 is formed in contact with second main surface 11a of silicon carbide single-crystal substrate 11. Silicon carbide epitaxial layer 13 includes an impurity element such as nitrogen. Silicon carbide epitaxial layer 13 has n type conductivity. Silicon carbide epitaxial layer 13 may be formed such that the impurity concentration of silicon carbide epitaxial layer 13 becomes lower than the impurity concentration of silicon carbide single-crystal substrate 11. The impurity concentration of silicon carbide epitaxial layer 13 is not less than about 1×10¹⁵ cm⁻³ and not more than about 1×10¹⁶ cm⁻³, for example. Moreover, silicon carbide epitaxial layer 13 may be formed such that the dislocation density of silicon carbide epitaxial layer 13 becomes lower than the dislocation density of silicon carbide single-crystal substrate 11.

Next, a silicon layer forming step (S30: FIG. 2) is performed. Specifically, referring to FIG. 1, silicon layer 2 is provided on and in contact with second surface 13a of silicon carbide epitaxial layer 13. Silicon layer 2 has a thickness of, for example, not less than 0.05 μm and not more than 0.1 μm, preferably, not more than 0.5 μm. Silicon layer 2 preferably covers the entire second surface 13a of silicon carbide epitaxial layer 13.

More specifically, referring to FIG. 5, the temperature of silicon carbide single-crystal substrate 11 having silicon carbide epitaxial layer 13 formed thereon is decreased from temperature A1 (time T3) to a temperature A2 (time T4). Temperature A2 of silicon carbide single-crystal substrate 11 having silicon carbide epitaxial layer 13 formed thereon is, for example, not less than 1100° C. and not more than 1300° C. Referring to FIG. 6 and FIG. 7, the carrier gas flows in the chamber during a period of time from T3 to T4, but no silicon carbide source material gas is introduced. Silicon carbide single-crystal substrate 11 having silicon carbide epitaxial layer 13 formed thereon is maintained at a substantially constant temperature A2 during a period of time from T4 to T5.

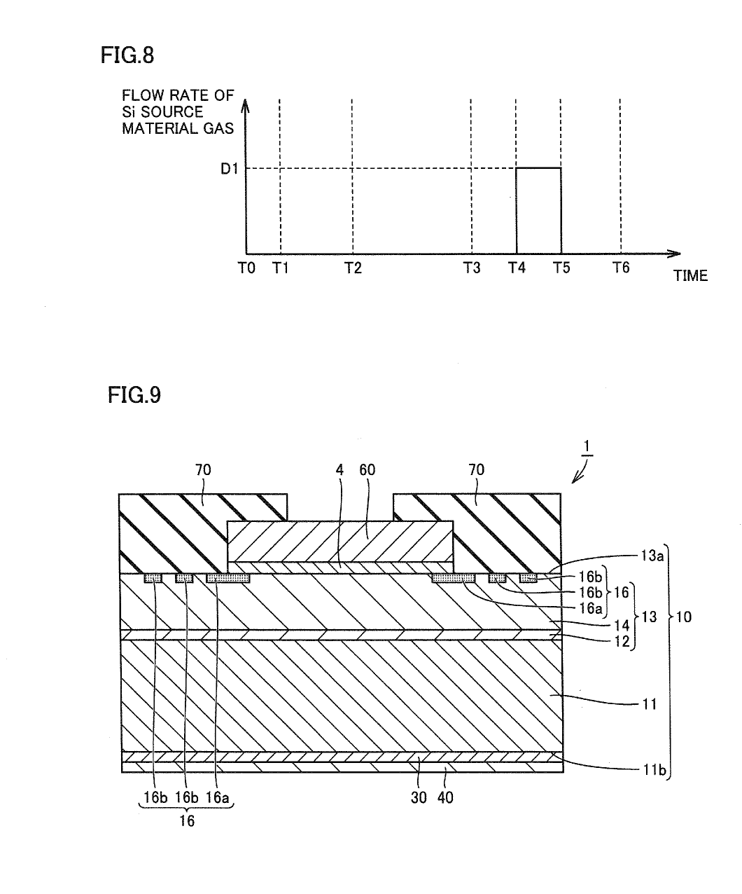

Next, referring to FIG. 8, silicon source material gas is introduced into the chamber while the temperature of silicon carbide single-crystal substrate 11 having silicon carbide epitaxial layer 13 formed thereon is at temperature A2. The silicon source material gas is silane, for example. The silicon source material gas is introduced into the chamber at a substantially constant flow rate D1 during a period of time from T4 to T5. Flow rate D1 of silane is about 50 sccm, for example. Accordingly, silicon layer 2 is formed on second surface 13a of silicon carbide epitaxial layer 13. Preferably, the silicon source material gas is gas included in the silicon carbide source material gas. In the present embodiment, the silicon source material gas is silane and the silicon carbide source material gas is gas including silane, propane, nitrogen, and ammonia. That is, the silicon source material gas is gas included in the silicon carbide source material gas. It should be noted that silicon layer 2 is preferably formed in a manner continuous to the formation of silicon carbide epitaxial layer 13 without bringing the temperature of silicon carbide epitaxial layer 13 back to a room temperature.

Preferably, the step of forming silicon carbide epitaxial layer 13 on silicon carbide single-crystal substrate 11 and the step of forming silicon layer 2 on silicon carbide epitaxial layer 13 are performed in the same chamber. In other words, after the step of forming silicon carbide epitaxial layer 13, silicon layer 2 is formed without removing, from the chamber, silicon carbide single-crystal substrate 11 having silicon carbide epitaxial layer 13 formed thereon. It should be noted that silicon carbide epitaxial layer 13 and silicon layer 2 may be formed in different chambers. In this case, for example, silicon carbide epitaxial layer 13 is formed on silicon carbide single-crystal substrate 11 in a first chamber. Thereafter, for example, silicon carbide single-crystal substrate 11 having silicon carbide epitaxial layer 13 formed thereon is transferred from the first chamber to a second chamber without exposing silicon carbide epitaxial layer 13 to atmospheric air. Then, silicon layer 2 may be formed on silicon carbide epitaxial layer 13 in the second chamber.

Next, at time T5, the introduction of the silicon source material gas to the chamber is stopped. Thereafter, the temperature of silicon carbide single-crystal substrate 11 having silicon layer 2 formed thereon is reduced from temperature A2 (time T5) to the room temperature (time T6). In this way, the formation of silicon carbide substrate 100 is completed which includes: silicon carbide single-crystal substrate 11; silicon carbide epitaxial layer 13 provided on and in contact with silicon carbide single-crystal substrate 11; and silicon layer 2 provided on and in contact with silicon carbide epitaxial layer 13.

The following describes function and effect of the silicon carbide substrate and the method for manufacturing it according to the present embodiment.

According to the method for manufacturing silicon carbide substrate 100 in the present embodiment, silicon layer 2 is formed in contact with second surface 13a of silicon carbide epitaxial layer 13. In this way, even when silicon carbide substrate 100 is stored under atmospheric air for a long period of time, light metal impurities, such as sodium and potassium, or organic impurities can be prevented from being attached to second surface 13a of silicon carbide epitaxial layer 13. Accordingly, silicon carbide epitaxial layer 13 can be prevented from being contaminated.

Further, according to the method for manufacturing silicon carbide substrate 100 in the present embodiment, silicon layer 2 has a thickness of not more than 0.5 μm. Accordingly, silicon layer 2 can be removed readily. Moreover, productivity in manufacturing silicon carbide substrate 100 can be improved.

Preferably, in the method for manufacturing silicon carbide substrate 100 according to the present embodiment, the step of forming silicon carbide epitaxial layer 13 and the step of forming silicon layer 2 are performed in the same chamber. Accordingly, silicon carbide epitaxial layer 13 can be effectively prevented from being contaminated.

According to silicon carbide substrate 100 in the present embodiment, silicon layer 2 is provided in contact with second surface 13a of silicon carbide epitaxial layer 13 opposite to first surface 13b that is in contact with silicon carbide single-crystal substrate 11. In this way, even when silicon carbide substrate 100 is stored under atmospheric air for a long period of time, light metal impurities, such as sodium and potassium, or organic impurities can be prevented from being attached to second surface 13a of the silicon carbide epitaxial layer. Accordingly, silicon carbide epitaxial layer 13 can be prevented from being contaminated.

Further, according to silicon carbide substrate 100 in the present embodiment, silicon layer 2 has a thickness of not more than 0.5 μm. Accordingly, silicon layer 2 can be removed readily. Moreover, productivity in manufacturing silicon carbide substrate 100 can be improved.

Further, according to silicon carbide substrate 100 in the present embodiment, silicon layer 2 covers the entire second surface 13a of silicon carbide epitaxial layer 13. Accordingly, second surface 13a of silicon carbide epitaxial layer 13 can be entirely protected, thereby more effectively preventing contamination of silicon carbide epitaxial layer 13.

### Second Embodiment

Referring to FIG. 9, the following describes a structure of a Schottky barrier diode 1 serving as a silicon carbide semiconductor device according to the present embodiment. As shown in FIG. 9, Schottky barrier diode 1 of the present embodiment mainly has a silicon carbide substrate 10, a Schottky electrode 4, an ohmic electrode 30, pad electrodes 40, 60, and protective films 70. Silicon carbide substrate 10 is formed of hexagonal crystal silicon carbide, and has n type conductivity (first conductivity type).

Silicon carbide substrate 10 has a silicon carbide single-crystal substrate 11 and a silicon carbide epitaxial layer 13. Silicon carbide epitaxial layer 13 has an electric field stop layer 12, an n type region 14, and a JTE (Junction Termination Extension) region 16, for example. Each of silicon carbide single-crystal substrate 11, electric field stop layer 12, and n type region 14 includes an impurity such as nitrogen, and has n type conductivity. The concentration of the impurity, such as nitrogen, in silicon carbide single-crystal substrate 11 is not less than about 1×10¹⁸ cm⁻³ and not more than about 1×10¹⁹ cm⁻³, for example. The concentration of the impurity, such as nitrogen, in electric field stop layer 12 is not less than about 5×10¹⁷ cm⁻³ and not more than about 1×10¹⁸ cm⁻³, for example. The concentration of the impurity, such as nitrogen, in n type region 14 is not less than about 1×10¹⁵ cm⁻³ and not more than about 1×10¹⁶ cm⁻³, for example.

JTE region 16 is a p type region having ions of an impurity such as aluminum (Al) or boron (B) implanted therein. The impurity concentration of the p type region is about 2×10¹⁷ cm⁻³, for example. JTE region 16 includes a p type region 16a in contact with the end portion of Schottky electrode 4 and p type regions 16b disposed at the outer circumferential side relative to p type region 16a and not in contact with Schottky electrode 4. Moreover, silicon carbide substrate 10 may have a field stop region (not shown) so as to surround JTE region 16. The field stop region is an n+ type region having ions of phosphorus (P) or the like implanted therein, for example.

Schottky electrode 4 is provided on second surface 13a of silicon carbide substrate 10, and is formed of titanium (Ti), for example. In addition to titanium, nickel (Ni), titanium nitride (TiN), gold (Au), molybdenum (Mo), tungsten (W), and the like can be used for Schottky electrode 4, for example. Pad electrode 60 is formed in contact with Schottky electrode 4. Pad electrode 60 is formed of aluminum, for example. Protective film 70 is formed in contact with pad electrode 60, Schottky electrode 4, and second surface 13a of silicon carbide substrate 10. Further, ohmic electrode 30 is disposed in contact with first main surface 11b of silicon carbide single-crystal substrate 11 opposite to second surface 13a. Ohmic electrode 30 is formed of nickel, for example. Pad electrode 40, which is formed of for example, titanium, nickel, silver, or an alloy thereof, is disposed in contact with ohmic electrode 30.

The following describes a method for manufacturing the Schottky barrier diode serving as the silicon carbide semiconductor device according to the present embodiment with reference to FIG. 1 and FIG. 10 to FIG. 13.

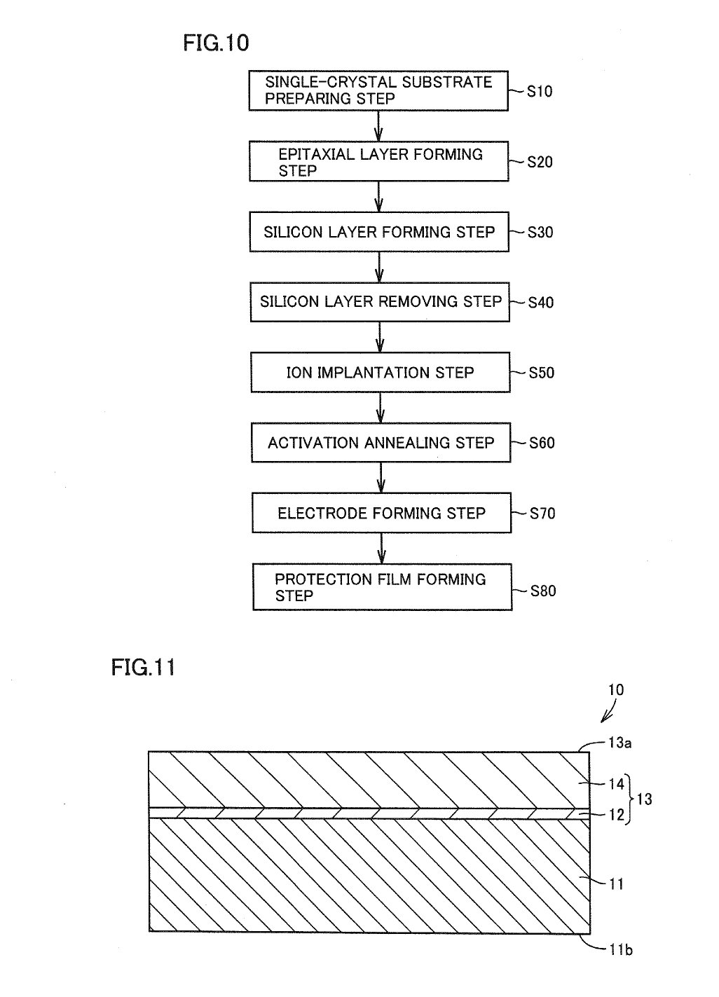

First, referring to FIG. 1, silicon carbide substrate 100 is prepared which includes: silicon carbide single-crystal substrate 11; silicon carbide epitaxial layer 13 provided in contact with second main surface 11a of silicon carbide single-crystal substrate 11; and silicon layer 2 provided in contact with second surface 13a of silicon carbide epitaxial layer 13. Silicon carbide substrate 100 may be prepared by performing the single-crystal substrate preparing step (S10: FIG. 2 and FIG. 10), the epitaxial layer forming step (S20: FIG. 2 and FIG. 10) and the silicon layer forming step (S30: FIG. 2 and FIG. 10) in accordance with the method for manufacturing silicon carbide substrate 100 as described in the first embodiment. Silicon carbide epitaxial layer 13 may include electric field stop layer 12 in contact with silicon carbide single-crystal substrate 11, and n type region 14 formed on electric field stop layer 12. Meanwhile, silicon carbide substrate 100 may be manufactured using a method different from the method described in the first embodiment.

Next, a silicon layer removing step (S40: FIG. 10) is performed. Specifically, silicon layer 2 is removed from second surface 13a of silicon carbide epitaxial layer 13. The removal of silicon layer 2 is attained by wet etching on the silicon layer using hydrofluoric-nitric acid, for example. The hydrofluoric-nitric acid is formed by mixing hydrofluoric acid and nitric acid at a volume ratio of 3 to 1, for example. Accordingly, as shown in FIG. 11, silicon layer 2 is removed from second surface 13a of silicon carbide epitaxial layer 13, thereby exposing second surface 13a.

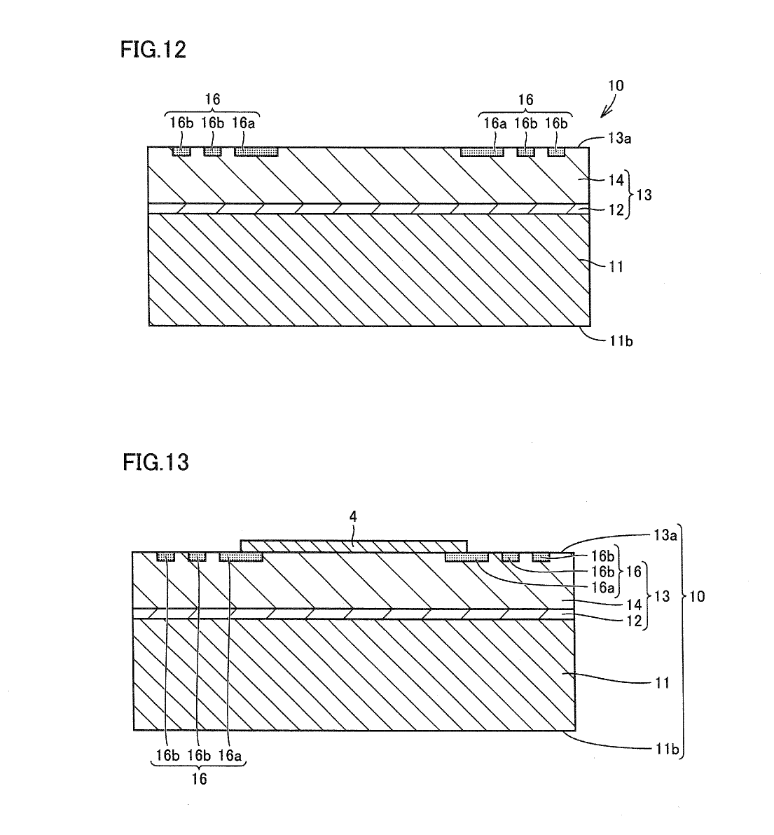

Next, the ion implantation step (S50: FIG. 10) is performed. Specifically, for example, a mask, which is formed of silicon dioxide and has an opening in conformity with regions to be provided with JTE region 16, is formed on second surface 13a of silicon carbide substrate 10. Thereafter, referring to FIG. 12, for example, Al (aluminum) ions are implanted into n type region 14, thereby forming JTE region 16 having p type conductivity (second conductivity type). The impurity concentration of JTE region 16 is about 2×10¹⁷ cm⁻³, for example.

Next, an activation annealing step (S60: FIG. 10) is performed. Specifically, for example, silicon carbide substrate 10 is heated at a temperature of about 1800° C. under an inert gas atmosphere such as argon, thereby annealing JTE region 16 and activating the impurity implanted in the above-described ion implantation step. Accordingly, desired carriers are generated in the regions having the impurity implanted therein.

Next, an electrode forming step (S70: FIG. 10) is performed. Specifically, Schottky electrode 4 is formed in contact with second surface 13a of silicon carbide substrate 10. Schottky electrode 4 is a metal film such as titanium (Ti), nickel (Ni), molybdenum (Mo), tungsten (W), and titanium nitride (TiN), for example. More specifically, referring to FIG. 13, Schottky electrode 4 is formed on second surface 13a of silicon carbide substrate 10 in contact with n type region 14 and p type regions 16a disposed at the inner circumference side.

Next, silicon carbide substrate 10 having Schottky electrode 4 formed thereon is heated. Schottky electrode 4 may be heated through, for example, laser annealing, or silicon carbide substrate 10 having Schottky electrode 4 formed thereon may be placed in a heating furnace and may be heated in an inert gas atmosphere. Schottky electrode 4 and silicon carbide substrate 10 are heated up to about 300° C., for example. Accordingly, Schottky electrode 4 and silicon carbide substrate 10 are in Schottky junction with each other. Next, pad electrode 60, which is formed of, for example, aluminum, is formed on and in contact with Schottky electrode 4.

Next, an ohmic electrode forming step is performed. Specifically, first main surface 11b of silicon carbide substrate 10 opposite to second surface 13a is grinded and ohmic electrode 30, which is formed of, for example, nickel, is formed in contact with first main surface 11b. Thereafter, pad electrode 40, which is formed of, for example titanium, nickel, silver, or an alloy thereof, is formed in contact with ohmic electrode 30.

Next, a protection film forming step (S80: FIG. 10) is performed. Specifically, for example, a plasma CVD method is employed to form protective film 70 in contact with pad electrode 60, Schottky electrode 4, and second surface 13a of silicon carbide substrate 10. Protective film 70 is formed of, for example, silicon dioxide, silicon nitride, or a laminated film thereof. Accordingly, Schottky barrier diode 1 serving as the silicon carbide semiconductor device shown in FIG. 9 is completed.

It should be noted that the Schottky barrier diode has been illustrated as the silicon carbide semiconductor device in the present embodiment, but the present invention is not limited to this. The silicon carbide semiconductor device may be a MOSFET, an IGBT (Insulated Gate Bipolar Transistor), or the like. Moreover, the MOSFET may be a planar type MOSFET or a trench type MOSFET. In the present embodiment, it has been assumed that the n type corresponds to the first conductivity type and the p type corresponds to the second conductivity type, but the silicon carbide semiconductor device may have a structure in which p type and n type are replaced with each other.

The following describes function and effect of the method for manufacturing Schottky barrier diode 1 serving as the silicon carbide semiconductor device according to the present embodiment.

According to the method for manufacturing Schottky barrier diode 1 in the present embodiment, silicon layer 2 is formed in contact with second surface 13a of silicon carbide epitaxial layer 13. Accordingly, silicon carbide epitaxial layer 13 can be prevented from being contaminated. This suppresses property deterioration of Schottky barrier diode 1.

Further, according to the method for manufacturing Schottky barrier diode 1 in the present embodiment, the step of removing silicon layer 2 is performed through wet etching on silicon layer 2 using hydrofluoric-nitric acid. Accordingly, silicon layer 2 can be efficiently removed.

Further, according to the method for manufacturing Schottky barrier diode 1 in the present embodiment, after the step of removing silicon layer 2, Schottky electrode 4 is formed on second surface 13a of silicon carbide epitaxial layer 13. Accordingly, Schottky electrode 4 is formed on second surface 13a of silicon carbide epitaxial layer 13 thus prevented from being contaminated, thereby preventing property deterioration of Schottky electrode 4.

Although the present invention has been described and illustrated in detail, it is clearly understood that the same is by way of illustration and example only and is not to be taken by way of limitation, the scope of the present invention being interpreted by the terms of the appended claims.

What is claimed is:

1. A method for manufacturing a silicon carbide substrate, comprising the steps of:
preparing a silicon carbide single-crystal substrate;
forming a silicon carbide epitaxial layer in contact with said silicon carbide single-crystal substrate; and
forming a silicon layer in contact with a second surface of said silicon carbide epitaxial layer opposite to a first surface thereof that makes contact with said silicon carbide single-crystal substrate.

2. The method for manufacturing the silicon carbide substrate according to claim 1, wherein said silicon layer has a thickness of not more than 0.5 μm.

3. The method for manufacturing the silicon carbide substrate according to claim 1, wherein the step of forming said silicon carbide epitaxial layer and the step of forming said silicon layer are performed in the same chamber.

4. A method for manufacturing a silicon carbide semiconductor device, comprising the steps of:
preparing a silicon carbide substrate manufactured using the method recited in claim 1; and
removing said silicon layer.

5. The method for manufacturing the silicon carbide semiconductor device according to claim 4, wherein the step of removing said silicon layer is performed through wet etching on said silicon layer using hydrofluoric-nitric acid.

6. The method for manufacturing the silicon carbide semiconductor device according to claim 4, wherein after the step of removing said silicon layer, an electrode is formed on said second surface of said silicon carbide epitaxial layer.

7. A silicon carbide substrate comprising:
a silicon carbide single-crystal substrate;
a silicon carbide epitaxial layer provided in contact with said silicon carbide single-crystal substrate; and
a silicon layer provided in contact with a second surface of said silicon carbide epitaxial layer opposite to a first surface thereof that makes contact with said silicon carbide single-crystal substrate.

8. The silicon carbide substrate according to claim 7, wherein said silicon layer has a thickness of not more than 0.5 μm.

9. The silicon carbide substrate according to claim 7, wherein said silicon layer entirely covers said second surface of said silicon carbide epitaxial layer.

10. A method for manufacturing a silicon carbide semiconductor device, comprising the steps of:
preparing a silicon carbide substrate recited in claim 7; and
removing said silicon layer.

11. The method for manufacturing the silicon carbide semiconductor device according to claim 10, wherein the step of removing said silicon layer is performed through wet etching on said silicon layer using hydrofluoric-nitric acid.

12. The method for manufacturing the silicon carbide semiconductor device according to claim 10, wherein after the step of removing said silicon layer, an electrode is formed on said second surface of said silicon carbide epitaxial layer.
